(19) United States
(12) Patent Application Publication
(10) Pub. No.: US 2007/0096819 A1
(43) Pub. Date: May 3, 2007

(54) CMOS amplifier

(75) Inventors: Makoto Yamamoto, Osaka (JP); Keiichi Fujii, Shiga (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/541,650

(22) Filed: Oct. 3, 2006

(30) Foreign Application Priority Data
Oct. 5, 2005 (JP) 2005-291942

(51) Int. Cl. H03F 3/45

(52) U.S. Cl. 330/255

(57) ABSTRACT

A CMOS amplifier according to the present invention includes an input stage, an output stage, a feedforward type idling current control circuit, and an interrupter circuit. The output stage includes a grounded-source push-pull circuit having an output P-channel MOS transistor and an output N-channel MOS transistor. The input stage includes two differential amplifier circuits. The idling current control circuit supplies idling currents to the MOS transistors of the output stage so that the MOS transistors of the output stage perform class AB amplification operations. The interrupter circuit includes a plurality of switches which are off in a stand-by state to stop power supply to the differential amplifier circuits, stop operations of constant current circuits included in the idling current control circuit, and cancel gate-source voltages at the MOS transistors of the output stage.

### BACKGROUND OF THE INVENTION

1. Field of the Invention

The present invention relates to a CMOS amplifier with a stand-by function in a semiconductor integrated circuit and to electronic equipment having the amplifier.

2. Background Art

As configurations of amplifier circuits such as audio output amplifiers, configurations of amplifier circuits including bipolar transistors and those of amplifier circuits including CMOS transistors have been heretofore proposed.

As an example of the configurations of such conventional CMOS amplifiers, there is the configuration of a CMOS amplifier described in Non-Patent Document 1 (“DESIGN OF LOW-VOLTAGE, LOW-POWER OPERATIONAL AMPLIFIER CELLS” by Ron Hogervorst and Johan H. Huijsing T. U. Delft Netherlands; KLUWER ACADEMIC PUBLISHERS).

FIG. 5 is a circuit diagram showing the configuration of the conventional CMOS amplifier disclosed in Non-Patent Document 1 described above. The CMOS amplifier of FIG. 5 includes a grounded-source push-pull output circuit which comprises a P-channel MOS transistor 4 and a N-channel MOS transistor 5 as an output stage 300.

And further, the CMOS amplifier has differential amplifier circuits 7 and 8 which drive the P-channel MOS transistor 4 for output and the N-channel MOS transistor 5 for output respectively in response to inputs from a plus input terminal 9 and a minus input terminal 10. The differential amplifier circuits 7 and 8 constitute a differential type input stage 100.

Still further, a feedforward type control circuit is used as an idling current control circuit 200 which makes the MOS transistors 4 and 5 perform class AB amplification operations, and therefore the feedforward type control circuit is able to operate at a low power supply voltage. The idling current control circuit 200 comprises P-channel MOS transistors 11, 12, 19, 20, 23, and 24, N-channel MOS transistors 15, 16, 21, 22, 25, and 26, and constant current circuits 14 and 18. Reference numeral 1 denotes a plus power supply terminal serving as a first power supply terminal, and reference numeral 2 denotes a minus power supply terminal (or a grounding terminal) serving as a second power supply terminal.

In addition, in Patent Document 1 (JP-A No. 11-103216), a CMOS amplifier whose distortion rate is reduced by enlarging a dynamic range is disclosed as another conventional CMOS amplifier.

In recent years, it has been required to provide portable electronic equipment, such as DVCs (digital video cameras), DSCs (digital still cameras), cellular phones, and notebook PCs, with low power consumption function such as a stand-by function and a power-saving function for use in performing stand-by operation and power-saving operation in a state in which power supply voltage is applied.

However, since such conventional CMOS amplifiers have no low power consumption function such as the stand-by function and the power-saving function, there is the problem that those equipment cannot be designed so as to have low power consumption.

In the configurations of the conventional amplifiers described above, currents which flow through the CMOS amplifiers in their stand-by state can be interrupted by decreasing gate-source voltages VGS's at all the MOS transistors below threshold voltages; however, to shut them off, there is a need to provide a switch for use in canceling each gate-source voltage VGS to each MOS transistor, and therefore their configurations increase in complexity.

### SUMMARY OF THE INVENTION

The present invention has been made to solve the conventional problem described above, and therefore an object of the invention is to provide a CMOS amplifier in which power supply current can be interrupted in a stand-by state by using only minimum necessary elements.

To solve the problem described above, the CMOS amplifier according to the invention includes an input stage, a push-pull type output stage, a feedforward type idling current control circuit, and an interrupter circuit.

The input stage comprises a first differential amplifier circuit and a second differential amplifier circuit.

The output stage comprises a first P-channel MOS transistor driven with an output signal from the first differential amplifier circuit and a first N-channel MOS transistor driven with an output signal from the second differential amplifier circuit.

The idling current control circuit comprises a first constant current circuit, a bias generating circuit for P-channel MOS transistors which generates a first bias voltage with a current supplied by the first constant current circuit, a second constant current circuit, a bias generating circuit for N-channel MOS transistors which generates a second bias voltage with a current supplied by the second constant current circuit, and an idling current supply circuit which supplies to the first P-channel MOS transistor an idling current corresponding to the first bias voltage generated by the bias generating circuit for the P-channel MOS transistors and which supplies to the first N-channel MOS transistor an idling current corresponding to the second bias voltage generated by the bias generating circuit for the N-channel MOS transistors.

The interrupter circuit comprises a first switch which interrupts power supply to the first and second differential amplifier circuits, a second switch which interrupts a current of the first constant current circuit, a third switch which interrupts a current of the second constant current circuit, a fourth switch which cancels a gate-source voltage at the first P-channel MOS transistor, a fifth switch which cancels the first bias voltage generated by the bias generating circuit for the P-channel MOS transistors, a sixth switch which cancels a gate-source voltage at the first N-channel MOS transistor, and a seventh switch which cancels the second bias voltage generated by the bias generating circuit for the N-channel MOS transistors.

In this configuration, no element whose drain has low impedance and whose gate has high impedance becomes present by providing the minimum necessary elements, i.e., the first switch which cuts off power supply to the first and second differential amplifier circuits, the second switch which interrupts the current of the first constant current circuit, the third switch which interrupts the current of the second constant current circuit, the fourth switch which cancels the gate-source voltage at the first P-channel MOS transistor, the sixth switch which cancels the gate-source voltage at the first N-channel MOS transistor, the fifth switch which cancels the first bias voltage generated by the bias generating circuit for the P-channel MOS transistors, and the seventh switch which cancels the second bias voltage generated by the bias generating circuit for the N-channel MOS transistors in the stand-by state. As a result, the power supply current can be interrupted (the stand-by state can be brought about).

It is preferable that the configuration described above includes the following configurations.

That is, the output stage has a configuration in which the source of the first P-channel MOS transistor is connected to a first power supply terminal, the source of the first N-channel MOS transistor is connected to a second power supply terminal, the drain of the first P-channel MOS transistor and the drain of the first N-channel MOS transistor are connected with each other, and an output terminal is connected to the drains of the first P-channel MOS transistor and the first N-channel MOS transistor.

The input stage has a configuration in which the first differential amplifier circuit receives power supply from the first and second power supply terminals, the minus input of the first differential amplifier circuit is connected to a first input terminal, the plus input of the first differential amplifier circuit is connected to a second input terminal, and the output of the first differential amplifier circuit is connected to the gate of the first P-channel MOS transistor and in which the second differential amplifier circuit receives power supply from the first and second power supply terminals, the minus input of the second differential amplifier circuit is connected to the first input terminal, the plus input of the second differential amplifier circuit is connected to the second input terminal, and the output of the second differential amplifier circuit is connected to the gate of the first N-channel MOS transistor.

The idling current control circuit has a configuration in which the bias generating circuit for the P-channel MOS transistors comprises a second P-channel MOS transistor whose source is connected to the first power supply terminal and whose gate and drain are connected with each other and a third P-channel MOS transistor whose source is connected to the gate and drain of the second P-channel MOS transistor and whose gate and drain are connected with-each other, one end of the first constant current circuit is connected to the gate and drain of the third P-channel MOS transistor, and the other end of the first constant current circuit is connected to the second power supply terminal and in which the bias generating circuit for the N-channel MOS transistors comprises a second N-channel MOS transistor whose source is connected to the second power supply terminal and whose gate and drain are connected with each other and a third N-channel MOS transistor whose source is connected to the gate and drain of the second N-channel MOS transistor and whose gate and drain are connected with each other, one end of the second constant current circuit is connected to the gate and drain of the third N-channel MOS transistor, and the other end of the second constant current circuit is connected to the first power supply terminal.

The idling current supply circuit comprises: a fourth P-channel MOS transistor whose gate is connected to the gate and drain of the third P-channel MOS transistor; a fifth P-channel MOS transistor whose gate is connected to the gate and drain of the third P-channel MOS transistor, whose source is connected to the gate of the first P-channel MOS transistor, and whose drain is connected to the gate of the first N-channel MOS transistor; a fourth N-channel MOS transistor whose gate is connected to the gate and drain of the third N-channel MOS transistor and whose drain and source are connected to the source and drain of the fourth P-channel MOS transistor respectively; a fifth N-channel MOS transistor whose gate is connected to the gate and drain of the third N-channel MOS transistor and whose drain and source are connected to the source and drain of the fifth P-channel MOS transistor respectively; a sixth P-channel MOS transistor whose drain and gate are connected to the source of the fourth P-channel MOS transistor and whose source is connected to the first power supply terminal; a seventh P-channel MOS transistor whose gate is connected to the source of the fourth P-channel MOS transistor, whose drain is connected to the source of the fifth P-channel MOS transistor, whose source is connected to the first power supply terminal, and which constitutes a first current mirror circuit together with the sixth P-channel MOS transistor; a sixth N-channel MOS transistor whose drain and gate are connected to the source of the fourth N-channel MOS transistor and whose source is connected to the second power supply terminal; and a seventh N-channel MOS transistor whose gate is connected to the source of the fourth N-channel MOS transistor, whose drain is connected to the source of the fifth N-channel MOS transistor, whose source is connected to the second power supply terminal, and which constitutes a second current mirror circuit together with the sixth N-channel MOS transistor.

The interrupter circuit has a configuration in which the fifth switch cancels double a gate-source voltage generated at the second and third P-channel MOS transistors and the seventh switch cancels double a gate-source voltage generated at the second and third N-channel MOS transistors.

And furthermore, it is preferable that the interrupter circuit have the following configuration. That is, the interrupter circuit further includes a first interrupting terminal at which a voltage drops to a voltage at the second power supply terminal or below threshold voltages at P-channel MOS transistors in a state other than a normal operation state and a second interrupting terminal at which a voltage rises to a voltage at the first power supply terminal or above threshold voltages at the N-channel MOS transistors in the state other than the normal operation state. And the fourth switch is provided in the form of an eighth P-channel MOS transistor which has a gate connected to the first interrupting terminal, a source connected to the first power supply terminal, and a drain connected to the gate of the first P-channel MOS transistor and which cancels the gate-source voltage at the first P-channel MOS transistor. The fifth switch is provided in the form of a ninth P-channel MOS transistor which has a gate connected to the first interrupting terminal, a source connected to the first power supply terminal, and a drain connected to the gate and drain of the third P-channel MOS transistor and which cancels double a gate-source voltage generated at the second and third P-channel MOS transistors. The sixth switch is provided in the form of an eighth N-channel MOS transistor which has a gate connected to the second interrupting terminal, a source connected to the second power supply terminal, and a drain connected to the gate of the first N-channel MOS transistor and which cancels the gate-source voltage at the first N-channel MOS transistor. The seventh switch is provided in the form of a ninth N-channel MOS transistor which has a gate connected to the second interrupting terminal, a source connected to the second power supply terminal, and a drain connected to the gate and drain of the third N-channel MOS transistor and which cancels double a gate-source voltage generated at the second and third N-channel MOS transistors.

And further, in the configuration described above, it is preferable that tenth and eleventh P-channel MOS transistors be cascode-connected to the sixth and seventh P-channel MOS transistors respectively, the gates of the tenth and eleventh P-channel MOS transistors be connected in common with the gates of the sixth and seventh P-channel MOS transistors, tenth and eleventh N-channel MOS transistors be cascode-connected to the sixth and seventh N-channel MOS transistors respectively, and the gates of the tenth and eleventh N-channel MOS transistors be connected in common with the gates of the sixth and seventh N-channel MOS transistors.

Still further, it is preferable that a resistor be provided between the output terminal and a grounding terminal.

In addition, with this CMOS amplifier, a video circuit and a voice circuit may be provided onto the same LSI.

As described above, the CMOS amplifier according to the present invention includes no element whose drain has low impedance and whose gate has high impedance by providing the minimum necessary switching circuits instead of taking measures against all high-impedance gates, and therefore the power supply current can be interrupted.

### BRIEF DESCRIPTION OF THE DRAWINGS

FIG. 1 is a circuit diagram showing the configuration of a CMOS amplifier according to a first embodiment of the present invention;

FIG. 2 is a circuit diagram showing the configuration of a CMOS amplifier according to a second embodiment of the invention;

FIG. 3 is a circuit diagram showing the configuration of a CMOS amplifier according to a third embodiment of the invention;

FIG. 4 is a circuit diagram showing the configuration of a CMOS amplifier according to a fourth embodiment of the invention; and

FIG. 5 is a circuit diagram showing the configuration of a conventional CMOS amplifier.

### DESCRIPTION OF THE EXEMPLARY EMBODIMENTS

Embodiments according to the present invention will be described below with reference to the drawings.

### First Embodiment

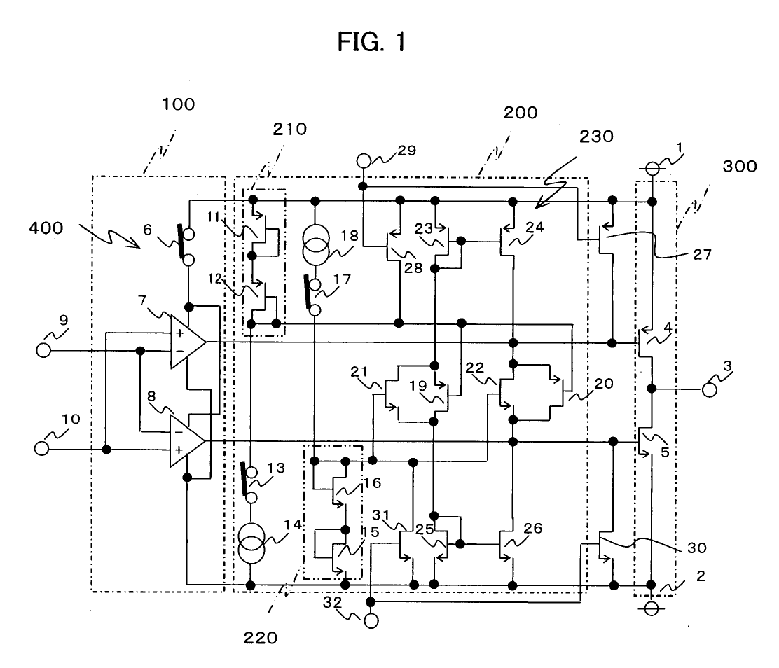

FIG. 1 is a circuit diagram showing the configuration of a CMOS amplifier according to the first embodiment of the invention. In a push-pull type output stage 300 of FIG. 1, a grounded-source push-pull circuit, which comprises a P-channel MOS transistor 4 for push side output and a N-channel MOS transistor 5 for pull side output, is connected between a plus power supply terminal 1 serving as a first power supply terminal and a minus power supply terminal (or a GND terminal) 2 serving as a second power supply terminal.

A differential type input stage 100 comprises first and second differential amplifier circuits 7 and 8. The differential amplifier circuits 7 and 8 amplify signals inputted from a plus input terminal 9 and a minus input terminal 10 to drive the P-channel MOS transistor 4 and the N-channel MOS transistor 5 respectively. As a result, signals produced by amplifying the signals inputted from the plus input terminal 9 and the minus input terminal 10 are outputted from an output terminal 3.

In addition, the CMOS amplifier is provided with an idling current control circuit 200 for use in making the push-pull circuit comprised of the P-channel MOS transistor 4 and the N-channel MOS transistor 5 perform a class AB operation. The idling current control circuit 200 determines idling currents which flow during noninput, that is, electric currents which flow into the P-channel MOS transistor 4 for push side output and the P-channel MOS transistor 5 for pull side output during noninput. The idling current control circuit 200 comprises P-channel MOS transistors 11, 12, 19, 20, 23, and 24, N-channel MOS transistors 15, 16, 21, 22, 25, and 26, and constant current circuits 14 and 18.

The configuration of the CMOS amplifier will be described below in detail.

The idling current control circuit 200 comprises the first constant current circuit 14, a bias-generating circuit 210 for the P-channel MOS transistors which generates a first bias voltage through the use of an electric current supplied by the first constant current circuit 14, the second constant current circuit 18, a bias-generating circuit 220 for the N-channel MOS transistors which generates a second bias voltage through the use of an electric current supplied by the second constant current circuit 18, and an idling current supply circuit 230 which supplies to the first P-channel MOS transistor 4 an idling current corresponding to the first bias voltage generated by the bias generating circuit 210 for the P-channel MOS transistors and which supplies to the first N-channel MOS transistor 5 an idling current corresponding to the second bias voltage generated by the bias generating circuit 220 for the N-channel MOS transistors.

In the output stage 300, the source of the first P-channel MOS transistor 4 is connected to the first power supply terminal 1, the source of the first N-channel MOS transistor 5 is connected to the second power'supply terminal 2, the drain of the first P-channel MOS transistor 4 and the drain of the first N-channel MOS transistor 5 are connected with each other, and the output terminal 3 is connected to the drains of the first P-channel MOS transistor 4 and the first N-channel MOS transistor 5.

In the input stage 100, the first differential amplifier circuit 7 receives power supply from the first power supply terminal 1 and the second power supply terminal 2, the minus input of the first differential amplifier circuit 7 is connected to the first input terminal 9, the plus input of the first differential amplifier circuit 7 is connected to the second input terminal 10, and the output of the first differential amplifier circuit 7 is connected to the gate of the first P-channel MOS transistor 4.

As well, the second differential amplifier circuit 8 receives power supply from the first power supply terminal 1 and the second power supply terminal 2, the minus input of the second differential amplifier circuit 8 is connected to the first input terminal 9, the plus input of the second differential amplifier circuit 8 is connected to the second input terminal 10, and the output of the second differential amplifier circuit 8 is connected to the gate of the first N-channel MOS transistor 5.

In the idling current control circuit 200, the bias generating circuit 210 for the P-channel MOS transistors comprises the second P-channel MOS transistor 11 whose source is connected to the first power supply terminal 1 and whose gate and drain are connected with each other and the third P-channel MOS transistor 12 whose source is connected to the gate and drain of the second P-channel MOS transistor 11 and whose gate and drain are connected with each other. One end of the first constant current circuit 14 is connected to the gate and drain of the third P-channel MOS transistor 12, and the other end of the first constant current circuit 14 is connected to the second power supply terminal 2.

As well, the bias generating circuit 220 for the N-channel MOS transistors comprises the second N-channel MOS transistor 15 whose source is connected to the second power supply terminal 2 and whose gate and drain are connected with each other and the third N-channel MOS transistor 16 whose source is connected to the gate and drain of the second N-channel MOS transistor 15 and whose gate and drain are connected with each other. One end of the second constant current circuit 18 is connected to the gate and drain of the third N-channel MOS transistor 16, and the other end of the second constant current circuit 18 is connected to the first power supply terminal 1.

The idling current supply circuit 230 comprises: the fourth P-channel MOS transistor 19 whose gate is connected to the gate and drain of the third P-channel MOS transistor 12; the fifth P-channel MOS transistor 20 whose gate is connected to the gate and drain of the third P-channel MOS transistor 12, whose source is connected to the gate of the first P-channel MOS transistor 4, and whose drain is connected to the gate of the first N-channel MOS transistor 5; the fourth N-channel MOS transistor 21 whose gate is connected to the gate and drain of the third N-channel MOS transistor 16 and whose drain and source are connected to the source and drain of the fourth P-channel MOS transistor 19 respectively; the fifth N-channel MOS transistor 22 whose gate is connected to the gate and drain of the third N-channel MOS transistor 16 and whose drain and source are connected to the source and drain of the fifth P-channel MOS transistor 20 respectively; the sixth P-channel MOS transistor 23 whose drain and gate are connected to the source of the fourth P-channel MOS transistor 19 and whose source is connected to the first power supply terminal 1; the seventh P-channel MOS transistor 24 whose gate is connected to the source of the fourth P-channel MOS transistor 19, whose drain is connected to the source of the fifth P-channel MOS transistor 20, whose source is connected to the first power supply terminal 1, and which constitutes a first current-mirror circuit together with the sixth P-channel MOS transistor 23; the sixth N-channel MOS transistor 25 whose drain and gate are connected to the source the fourth N-channel MOS transistor 21 and whose source is connected to the second power supply terminal 2; and the seventh N-channel MOS transistor 26 whose gate is connected to the source of the fourth N-channel MOS transistor 21, whose drain is connected to the source of the fifth N-channel MOS transistor 22, whose source is connected to the second power supply terminal 2, and which constitutes a second current-mirror circuit together with the sixth N-channel MOS transistor 25.

In addition, the CMOS amplifier is provided with an interrupter circuit 400 for use in interrupting electric currents flowing to the input stage 100, the output stage 300, and the idling current control circuit 200 when the amplifier has been set to a stand-by state.

The interrupter circuit 400 comprises a switch 6 which interrupts power supply to the first and second differential amplifier circuits 7 and 8, a second switch 13 which interrupts an electric current of the first constant current circuit 14, a third switch 17 which interrupts an electric current of the second constant current circuit 18, a P-channel MOS transistor 27 serving as a fourth switch which cancels a gate-source voltage at the first P-channel MOS transistor 4, a P-channel MOS transistor 28 serving as a fifth switch which cancels a first bias voltage generated by the bias generating circuit 210 for the P-channel MOS transistors, a N-channel MOS transistor 30 serving as a sixth switch which cancels a gate-source voltage at the first N-channel MOS transistor 5, and a N-channel MOS transistor 31 serving as a seventh switch which cancels a second bias voltage generated by the bias generating circuit 220 for the N-channel MOS transistors. More specifically, in the interrupter circuit 400, the P-channel MOS transistor 28 serving as the fifth switch cancels double the gate-source voltage generated at the second and third P-channel MOS transistors 11 and 12, and the N-channel MOS transistor 31 serving as the seventh switch cancels double the gate-source voltage generated at the second and third N-channel MOS transistors 15 and 16.

The interrupter circuit 400 further includes a first interrupting terminal 29 at which voltage drops below a voltage at the second power supply terminal 2 or threshold voltages at the P-channel MOS transistors in a state other than a normal operation state and a second interrupting terminal 32 at which voltage rises above a voltage at the first power supply terminal 1 or threshold voltages at the N-channel MOS transistors in the state other than the normal operation state.

The eighth P-channel MOS transistor 27 serving as the fourth switch has a gate connected to the first interrupting terminal 29, a source connected to the first power supply terminal 1, and a drain connected to the gate of the first P-channel MOS transistor 4 and cancels the gate-source voltage at the first P-channel MOS transistor 4.

The ninth P-channel MOS transistor 28 serving as the fifth switch has a gate connected to the first interrupting terminal 29, a source connected to the first power supply terminal 1, and a drain connected to the gate and drain of the third P-channel MOS transistor 12 and cancels double the gate-source voltage generated at the second and third P-channel MOS transistors 11 and 12.

The eighth N-channel MOS transistor 30 serving as the sixth switch has a gate connected to the second interrupting terminal 32, a source connected to the second power supply terminal 2, and a drain connected to the gate of the first N-channel MOS transistor 5 and cancels the gate-source voltage at the first N-channel MOS transistor 5.

The ninth N-channel MOS transistor 31 serving as the seventh switch has a gate connected to the second interrupting terminal 32, a source connected to the second power supply terminal 2, and a drain connected to the gate and drain of the third N-channel MOS transistor 16 and cancels double the gate-source voltage generated at the second and third N-channel MOS transistors 15 and 16.

Incidentally, the switches 6, 13, 17 are also formed by using MOS transistors; however, in this embodiment, the above configuration is used in which electric currents are cut off by canceling gate-source voltages VGS's at the constant current circuits (the current mirror circuits) through the use of the MOS transistors. The MOS transistors can be controlled with signals from the interrupting terminals.

The switch 6 is on in the normal operation state under a control signal sent from the outside but off in the stand-by state. As a result, in the stand-by state, power supply currents to be supplied to the differential amplifier circuits 7 and 8 are interrupted, and therefore the operations of the differential amplifier circuits 7 and 8 are halted. The switches 13 and 17 are on in the normal operation state under control signals sent from the outside but off in the stand-by state. As a consequence, currents of the constant current circuits 14 and 18 are interrupted in the stand-by state.

The P-channel MOS transistors 27 and 28 are turned on or off according to voltages applied to the interrupting terminal 29. Specifically, the P-channel MOS transistors 27 and 28 are off in the normal operation state but on in the stand-by state. That is, in the stand-by state, the P-channel MOS transistors 27 and 28 are on because a voltage fed to the interrupting terminal 29 is brought to a voltage at the minus power supply terminal (or the GND terminal) 2 or decreased below the threshold voltages at the P-channel MOS transistors.

On the other hand, in the normal operation state, the P-channel MOS transistors 27 and 28 are off because the voltage fed to the interrupting terminal 29 is brought to a voltage at the plus power supply terminal 1 or increased above the threshold voltages at the P-channel MOS transistors.

As a result, in the stand-by state, the gate-source voltage VGS at the P-channel MOS transistor 4 for the push side output is canceled by the P-channel MOS transistor 27. At this time, a bias voltage (2 VGS's) generated by the P-channel MOS transistors 11 and 12 is also canceled by the P-channel MOS transistor 28.

Likewise, the N-channel MOS transistors 30 and 31 are turned on or off according to voltages applied to the interrupting terminal 32. Specifically, the N-channel MOS transistors 30 and 31 are off in the normal operation state but on in the stand-by state. That is, in the stand-by state, the N-channel MOS transistors 30 and 31 are on because a voltage fed to the interrupting terminal 32 is brought to the voltage at the plus power supply terminal 1 or increased above the threshold voltages at the N-channel MOS transistors.

On the other hand, in the normal operation state, the N-channel MOS transistors 30 and 31 are off because the voltage fed to the interrupting terminal 32 is brought to the voltage at the minus power supply terminal (or the GND terminal) 2 or decreased below the threshold voltages at the N-channel MOS transistors.

As a result, in the stand-by state, the gate-source voltage VGS at the N-channel MOS transistor 5 for the pull side output is canceled by the N-channel MOS transistor 30. At this time, a bias voltage (2 VGS's) generated by the N-channel MOS transistors 15 and 16 is also canceled by the N-channel MOS transistor 31.

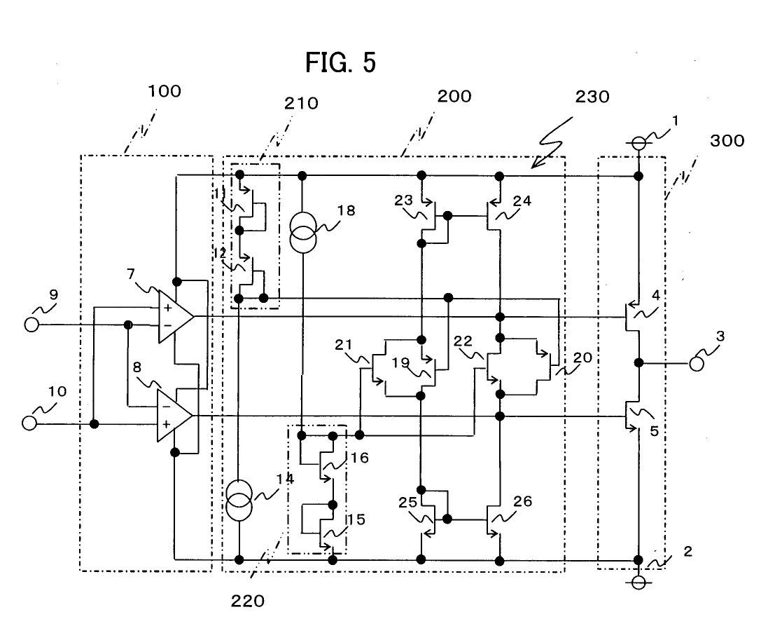

According to the CMOS amplifier of the first embodiment of the invention, such current interruption effected in the stand-by state can be implemented in the conventional CMOS amplifier of FIG. 5 by using the switches 6, 13, and 17, the P-channel MOS transistors 27 and 28 serving as switches, and the N-channel MOS transistors 30 and 31 serving as switches as minimum necessary elements.

That is, in this configuration, no element whose drain has low impedance and whose gate has high impedance becomes present by providing minimum necessary elements, i.e., the first switch 6 which interrupts power supply to the first and second differential amplifier circuits 7 and 8, the second switch 13 which interrupts a current of the first constant current circuit 14, the third switch 17 which interrupts a current of the second constant current circuit 18, the P-channel MOS transistor 27 serving as the fourth switch which cancels the gate-source voltage at the first P-channel MOS transistor, the N-channel MOS transistor 30 serving as the sixth switch which cancels the gate-source voltage at the first N-channel MOS transistor, the P-channel MOS transistor 28 serving as the fifth switch which cancels the first bias voltage generated by the bias generating circuit 210 for the P-channel MOS transistors, and the N-channel MOS transistor 31 serving as the seventh switch which cancels the second bias voltage generated by the bias generating circuit 220 for the N-channel MOS transistors in the stand-by state. As a consequence, the power supply current can be interrupted (the stand-by state can be brought about).

### Second Embodiment

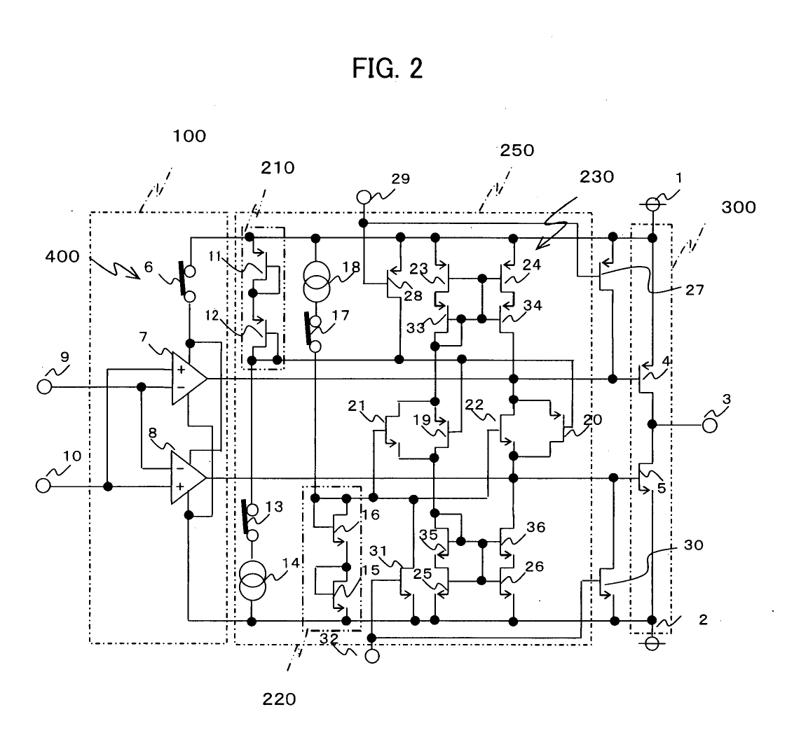

FIG. 2 is a circuit diagram showing the configuration of a CMOS amplifier according to a second embodiment of the invention. As shown in FIG. 2, in the second embodiment, an idling current control circuit 250 is used instead of the idling current control circuit 200. In the idling current control circuit 250, P-channel MOS transistors 33 and 34 are cascode-connected to the P-channel MOS transistors 23 and 24 respectively, and N-channel MOS transistors 35 and 36 are cascode-connected to the N-channel MOS transistors 25 and 26 respectively; however, the configuration other than those is the same as that shown in FIG. 1.

Specifically describing, the tenth and eleventh P-channel MOS transistors 33 and 34 are cascode-connected to the sixth and seventh P-channel MOS transistors 23 and 24 respectively and the gates of the tenth and eleventh P-channel MOS transistors 33 and 34 are connected in common with the gates of the sixth and seventh P-channel MOS transistors 23 and 24.

Likewise, the tenth and eleventh N-channel MOS transistors 35 and 36 are cascode-connected to the sixth and seventh N-channel MOS transistors 25 and 26 respectively and the gates of the tenth and eleventh N-channel MOS transistors 35 and 36 are connected in common with the gates of the sixth and seventh N-channel MOS transistors 25 and 26.

As described above, by cascode-connecting the MOS transistors 33, 34, 35, and 36 to the MOS transistors 23, 24, 25, and 26 respectively in the idling current control circuit 250, variations in current values can be reduced, and therefore variations in properties can be reduced.

In the second embodiment, advantages other than the above are the same as those described in the first embodiment.

### Third Embodiment

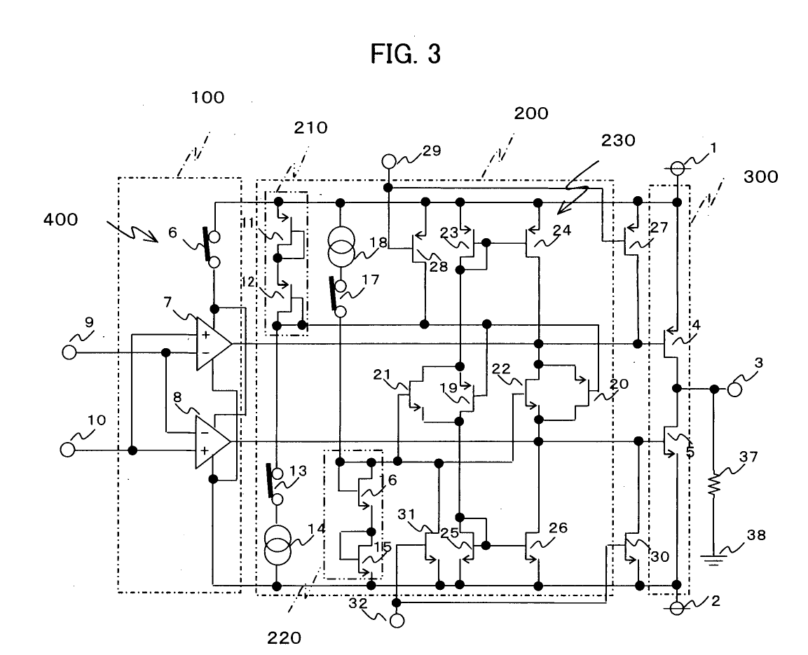

FIG. 3 is a circuit diagram showing the configuration of a CMOS amplifier according to a third embodiment of the present invention. As shown in FIG. 3, the third embodiment differs from the first embodiment in that a resistor 37 is inserted between the output terminal 3 and a GND (grounding) terminal 38.

By using such a configuration, a potential at the output terminal 3 is fixed at a GND potential in the stand-by state, and therefore no unfixed potential is generated. As a result, defects such as leakage of current can be detected at the P-channel MOS transistor 4 for the push side output and the N-channel MOS transistor 5 for the pull side output. The configuration other than the above is the same as that shown in FIG. 1.

With this embodiment, the defects, such as leakage of current, caused at the transistors are detected as follows: if a leakage current Ip has occurred at the P-channel MOS transistor 4, a DC voltage at the output terminal 3 reaches R37×Ip (where R37 is the resistance value of the resistor 37); as well, if a leakage current In has occurred at the N-channel MOS transistor 5, a DC voltage at the output terminal 3 reaches R37×In; when no leakage current occurs, the output terminal 3 has the ground potential; and therefore the leakages occurring at the MOS transistors can be detected by the potential at the output terminal 3.

With the third embodiment, advantages other than the above are the same as those described in the first embodiment.

### Fourth Embodiment

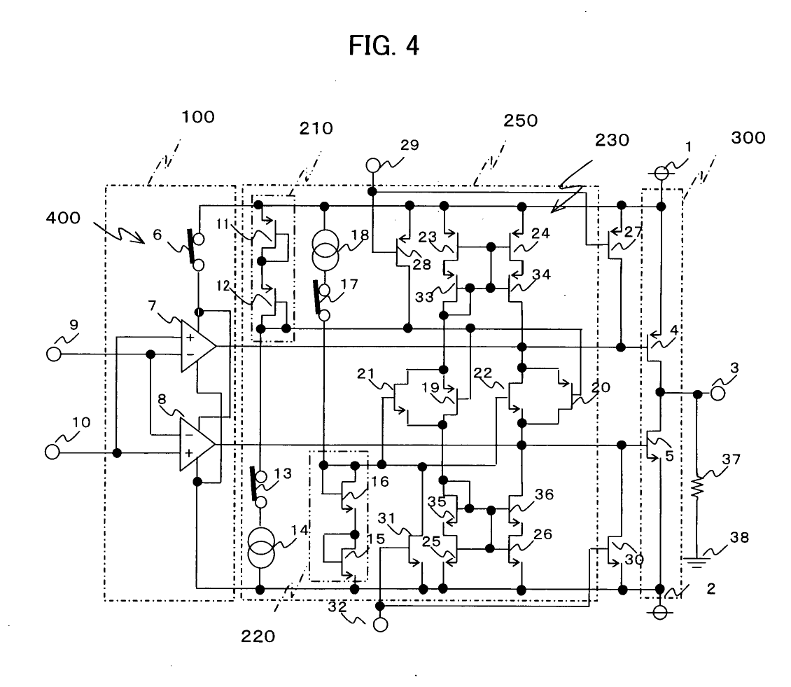

FIG. 4 is a circuit diagram showing the configuration of a CMOS amplifier according to a fourth embodiment of the invention. As shown in FIG. 4, the fourth embodiment differs from the second embodiment in that the resistor 37 is inserted between the output terminal 3 and the GND (grounding) terminal 38.

By using such a configuration, the potential at the output terminal 3 is fixed at the GND potential in the stand-by state, and therefore no unfixed potential is generated. As a consequence, defects such as leakage of current can be detected at the P-channel MOS transistor 4 for the push side output and the N-channel MOS transistor 5 for the pull side output. The configuration other than the above is the same as that shown in FIG. 2.

With the fourth embodiment, advantages other than the above are the same as those described in the second embodiment.

Incidentally, with the CMOS amplifier, a video circuit and a voice circuit may be provided onto the same LSI.

### INDUSTRIAL APPLICABILITY

The CMOS amplifier according to the present invention is useful as output circuits employed in portable electronic equipment such as DVCs (digital video cameras), DSCs (digital still cameras), cellular phones, and notebook PCs.

1. A CMOS amplifier comprising:
a differential type input stage which comprises first and second differential amplifier circuits;
a push-pull type output stage which comprises a first P-channel MOS transistor driven with an output signal from the first differential amplifier circuit and a first N-channel MOS transistor driven with an output signal from the second differential amplifier circuit;
a feedforward type idling current control circuit which comprises a first constant current circuit, a bias generating circuit for P-channel MOS transistors which generates a first bias voltage with a current supplied by the first constant current circuit, a second constant current circuit, a bias generating circuit for N-channel MOS transistors which generates a second bias voltage with a current supplied by the second constant current circuit, and an idling current supply circuit which supplies to the first P-channel MOS transistor an idling current corresponding to the first bias voltage generated by the bias generating circuit for the P-channel MOS transistors and which supplies to the first N-channel MOS transistor an idling current corresponding to the second bias voltage generated by the bias generating circuit for the N-channel MOS transistors; and
an interrupter circuit which comprises a first switch which interrupts power supply to the first and second differential amplifier circuits, a second switch which interrupts a current of the first constant current circuit, a third switch which interrupts a current of the second constant current circuit, a fourth switch which cancels a gate-source voltage at the first P-channel MOS transistor, a fifth switch which cancels a first bias voltage generated by the bias generating circuit for the P-channel MOS transistors, a sixth switch which cancels a gate-source voltage at the first N-channel MOS transistor, and a seventh switch which cancels a second bias voltage generated by the bias generating circuit for the N-channel MOS transistors.

2. The CMOS amplifier according to claim 1, wherein
the output stage has a configuration in which
the source of the first P-channel MOS transistor is connected to a first power supply terminal, the source of the first N-channel MOS transistor is connected to a second power supply terminal, the drain of the first P-channel MOS transistor and the drain of the first N-channel MOS transistor are connected with each other, and an output terminal is connected to the drains of the first P-channel MOS transistor and the first N-channel MOS transistor,
the input stage has a configuration in which
the first differential amplifier circuit receives power supply from the first and second power supply terminals, the minus input of the first differential amplifier circuit is connected to a first input terminal, the plus input of the first differential amplifier circuit is connected to a second input terminal, and the output of the first differential amplifier circuit is connected to the gate of the first P-channel MOS transistor and in which
the second differential amplifier circuit receives power supply from the first and second power supply terminals, the minus input of the second differential amplifier circuit is connected to the first input terminal, the plus input of the second differential amplifier circuit is connected to the second input terminal, and the output of the second differential amplifier circuit is connected to the gate of the first N-channel MOS transistor,
the idling current control circuit has a configuration in which
the bias generating circuit for the P-channel MOS transistors comprises a second P-channel MOS transistor whose source is connected to the first power supply terminal and whose gate and drain are connected with each other and a third P-channel MOS transistor whose source is connected to the gate and drain of the second P-channel MOS transistor and whose gate and drain are connected with each other, one end of the first constant current circuit is connected to the gate and drain of the third P-channel MOS transistor, the other end of the first constant current circuit is connected to the second power supply terminal,
the bias generating circuit for the N-channel MOS transistors comprises a second N-channel MOS transistor whose source is connected to the second power supply terminal and whose gate and drain are connected with each other and a third N-channel MOS transistor whose source is connected to the gate and drain of the second N-channel MOS transistor and whose gate and drain are connected with each other, one end of the second constant current circuit is connected to the gate and drain of the third N-channel MOS transistor, and the other end of the second constant current circuit is connected to the first power supply terminal,
the idling current supply circuit comprises:
a fourth P-channel MOS transistor having a gate connected to the gate and drain of the third P-channel MOS transistor;
a fifth P-channel MOS transistor having a gate connected to the gate and drain of the third P-channel MOS transistor, a source connected to the gate of the first P-channel MOS transistor, and a drain connected to the gate of the first N-channel MOS transistor;
a fourth N-channel MOS transistor having a gate connected to the gate and drain of the third N-channel MOS transistor and having a drain and a source which are connected to the source and drain of the fourth P-channel MOS transistor respectively; a fifth N-channel MOS transistor having a gate connected to the gate and drain of the third N-channel MOS transistor and having a drain and a source which are connected to the source and drain of the fifth P-channel MOS transistor respectively;
a sixth P-channel MOS transistor having a drain and a gate which are connected to the source of the fourth P-channel MOS transistor and having a source connected to the first power supply terminal;
a seventh P-channel MOS transistor having a gate connected to the source of the fourth P-channel MOS transistor, a drain connected to the source of the fifth P-channel MOS transistor, and a source connected to the first power supply terminal and constituting a first current-mirror circuit together with the sixth P-channel MOS transistor;
a sixth N-channel MOS transistor having a drain and a gate which are connected to the source of the fourth N-channel MOS transistor and having a source connected to the second power supply terminal; and
a seventh N-channel MOS transistor having a gate connected to the source of the fourth N-channel MOS transistor, a drain connected to the source of the fifth N-channel MOS transistor, and a source connected the second power supply terminal and constituting a second current-mirror circuit together with the sixth N-channel MOS transistor, and
the interrupter circuit has a configuration in which the fifth switch cancels double a gate-source voltage generated at the second and third P-channel MOS transistors and the seventh switch cancels double a gate-source voltage generated at the second and third N-channel MOS transistors.

3. The CMOS amplifier according to claim 2, wherein
the interrupter circuit further includes:
a first interrupting terminal at which a voltage drops to a voltage at the second power supply terminal or below threshold voltages at the P-channel MOS transistors in a state other than a normal operation state; and
a second interrupting terminal at which a voltage rises to a voltage at the first power supply terminal or above threshold voltages at the N-channel MOS transistors in the state other than the normal operation state,
the fourth switch is provided in the form of an eighth P-channel MOS transistor which has a gate connected to the first interrupting terminal, a source connected to the first power supply terminal, and a drain connected to the gate of the first P-channel MOS transistor and which cancels a gate-source voltage at the first P-channel MOS transistor,
the fifth switch is provided in the form of a ninth P-channel MOS transistor which has a gate connected to the first interrupting terminal, a source connected to the first power supply terminal, and a drain connected to the gate and drain of the third P-channel MOS transistor and which cancels double a gate-source voltage generated at the second and third P-channel MOS transistors,
the sixth switch is provided in the form of an eighth N-channel MOS transistor which has a gate connected to the second interrupting terminal, a source connected to the second power supply terminal, and a drain connected to the gate of the first N-channel MOS transistor and which cancels a gate-source voltage at the first N-channel MOS transistor, and
the seventh switch is provided in the form of a ninth N-channel MOS transistor which has a gate connected to the second interrupting terminal, a source connected to the second power supply terminal, and a drain connected to the gate and drain of the third N-channel MOS transistor and which cancels double a gate-source voltage generated at the second and third N-channel MOS transistors.

4. The CMOS amplifier according to claim 3, wherein
tenth and eleventh P-channel MOS transistors are cascode-connected to the sixth and seventh P-channel MOS transistors respectively, the gates of the tenth and eleventh P-channel MOS transistors are connected in common with the gates of the sixth and seventh P-channel MOS transistors,
tenth and eleventh N-channel MOS transistors are cascode-connected to the sixth and seventh N-channel MOS transistors respectively, and the gates of the tenth and eleventh N-channel MOS transistors are connected in common with the gates of the sixth and seventh N-channel MOS transistors.

5. The CMOS amplifier according to claim 1, wherein a resistor is provided between the output terminal and the grounding terminal.
